(19) United States
(12) Patent Application Publication
(10) Pub. No.: US 2008/0003456 A1
(43) Pub. Date: Jan. 3, 2008

(54) METHODS FOR PRODUCING ELECTROLUMINESCENT DEVICES BY SCREEN PRINTING

(75) Inventors: Arthur J. Epstein, Bexley, OH (US); Yunzhang Wang, Duncan, SC (US)

Correspondence Address: STANDLEY LAW GROUP LLP, 495 METRO PLACE SOUTH, SUITE 210, DUBLIN, OH, 43017, US

(73) Assignee: The Ohio State University, Columbus, OH (US)

(21) Appl. No.: 11/837,930

(22) Filed: Aug. 13, 2007

Related U.S. Application Data
(63) Continuation of application No. 10/196,523, filed on Jul. 16, 2002, now abandoned.
(60) Provisional application No. 60/308,276, filed on Jul. 27, 2001.

(51) Int. Cl. B32B 9/00

(52) U.S. Cl. 428/690

(57) ABSTRACT

The present invention includes methods for fabricating polymer light emitting devices by screen-printing. These light emitting devices use silver paste as the top electrode, eliminating the use of evaporated low work function metal. This is made possible by the presence of a buffer layer such as the sulfonated polyaniline layer in the structure of SCALE devices. These devices allow a very inexpensive and fast means to form stable top electrodes for large-scale polymer light emitting device fabrication.

This application is a continuation of U.S. patent application Ser. No. 10/196,523, filed Jul. 16, 2002, which claims the benefit of U.S. Provisional Patent Application No. 60/308,276, filed Jul. 27, 2001, both of which are incorporated herein by reference.

The present invention arose through work supported in part by Office of Naval Research. The United States Government may have certain rights to this invention under 35 U.S.C. Section 200 et seq.

### TECHNICAL FIELD OF THE INVENTION

This invention relates to light-emitting devices driven by an electric field and which are commonly referred to as electroluminescent devices. BACKGROUND OF THE INVENTION

Conjugated polymers have proven to be excellent candidates for low cost large area display applications, due to unique properties such as electroluminescence (EL), solution processibility, band gap tunability and mechanical flexibility. A major advantage of the conjugated polymer light emitting devices (LEDs) is their potential capability of using web based roll-to-roll processing. If realized, the manufacturing cost of polymer LEDs for large area applications may be significantly reduced. In the past few years, polymer LEDs have made remarkable progress toward commercialization, though the effort is mainly focused on small-area applications.

Typical single layer polymer LEDs are constructed by sandwiching a thin layer of luminescent conjugated polymer between two electrodes, an anode and a cathode, where at least one of the electrodes is either transparent or semi-transparent. In some multilayer devices, charge injection and transport layers may be incorporated to improve the device performance. For selected multilayer devices, electrons and holes combine at the interfaces to form exciplexes that emit light of a different color than either of the polymers comprising the interface. When a high electric field is applied between the electrodes in these devices, electrons are injected from the cathode and holes injected from the anode into the polymer layers. The injected charges recombine and decay radiatively to emit light. The double charge injection mechanism of such polymer LEDs requires matching of the cathode (anode) work function to the corresponding LUMO (HOMO) level of the polymer with which the electrode is in contact, in order to achieve efficient charge injection. Indium-tin-oxide (ITO) is widely used as the anode material for polymer LEDs because it is conductive, transparent and has a relatively high work function that is close to the HOMO level of many conjugated polymers. Because most conjugated polymers have relatively low electron affinity, however, they require metals with low work functions as the cathode material to achieve efficient electron injection. Low work function metals are generally oxygen reactive, leading to which are usually unstable. Devices with low work function cathodes may even degrade during storage.

In a typical polymer LED, the polymer layers are formed by spin-casting or other similar techniques, such as dip-coating, that are more suitable for large area processing. The cathode, on the other hand, is almost exclusively formed by vacuum deposition techniques such as thermal evaporation or sputtering of low work function metals or alloys. These vacuum deposition techniques are expensive, slow, and not well suited for large area processing.

It is thus an object of the present invention to provide a method of fabrication that provides a fast, inexpensive means of fabricating polymer light emitting devices suitable for large area applications.

Although described with respect to the field of light-emitting devices driven by an electric field, it will be appreciated that similar advantages of fast, inexpensive fabrication, as well as other advantages, may obtain in other applications of the present invention. Such advantages may become apparent to one of ordinary skill in the art in light of the present disclosure or through practice of the invention.

### SUMMARY OF THE INVENTION

The present invention includes electroluminescent polymer devices and electroluminescent polymer systems. The present invention also includes machines and instruments using those aspects of the invention. Included in the present invention are methods for the fabrication of such devices by screen printing. The methods of the present invention may be applied using procedures and protocols known and used in the arts to which they pertain. The methods of the present invention may be used to manufacture unipolar LED devices, bipolar SCALE devices and bipolar two-color SCALE devices. The present invention may be used to upgrade, repair, or retrofit existing machines or instruments using those aspects of the invention, using methods and components used in the art.

Method for Preparing a Layered Composite

In broadest terms, the method of the present invention for preparing a layered composite capable of forming a light-emitting device comprises the steps of: (1) obtaining a substrate material comprising a layer of an electrode material; (2) forming an emitting layer on the substrate material, the emitting layer capable of functioning as a light-emitting layer in a light-emitting device; and (3) applying a conductive paste material to the emitting layer, such as silver paste, the conductive paste material comprising a layer of an electrode material. The emitting layer may also be coated with an appropriate buffer layer prior to application of said conductive paste material, such as a layer of an appropriate semiconducting or conducting polymer.

The conductive paste material may applied by a technique such as painting, spraying, or screen-printing. The substrate material may consist of a material such as flexible ITO-coated PET or ITO-coated glass, thus the substrate may be either flexible or rigid. The substrate material may also be substantially impermeable to either oxygen or water. The emitting layer may be selected from the group consisting of light emitting molecules, oligomers, polymers, their derivatives and blends thereof. Further the emitting layer may itself be comprised of multiple layers. In the case of a multi-layered emitting layer, each sub-layer of the multi-layered emitting layer may be separately chosen from light emitting molecules, oligomers and polymers. The semiconducting and conducting polymers may be selected from the group consisting of polyanilines, polythiophenes, polypyrroles, their derivatives, their copolymers and blends thereof.

The electrodes of the present invention may be patterned, such as for pixelation.

Examples of conductive pastes that may be used in the present invention include: silver paste, gold paste, graphite paste, carbon paste or other particulate conductors dispersed in a medium allowing it to be applied by printing or screen printing technologies.

Examples of light emitting molecules that may be used in the emitting layer include: tris(8-quinolinolato)aluminum, bis(2-(2-hydroxyphenyl)pyridinato)beryllium, anthracene, tris(2-phenylpyridine)iridium doped in a host of 4,4′-N,N′-dicarbazol-biphenyl, their derivatives and blends thereof.

Examples of light emitting oligomers that may be used in the emitting layer include: oligo(phenylenevinylene)s, sexithiophene, oligo(thiophene)s, oligo(pyridine)s, their derivatives and blends thereof.

Examples of light emitting polymers that may be used in the emitting layer include: poly(arylene vinylene)s, poly(phenylene)s, poly(fluorene)s, poly(vinyl carbazole), poly(pyridine), poly(pyridyl vinylene), poly(phenylene vinylene pyridyl vinylene), their derivatives, their copolymers and blends thereof.

Layered Composite

Also included in the present invention is, in broadest terms, a layered composite capable of forming a light-emitting device comprising: (1) a substrate material comprising a layer of an electrode material; (2) an emitting layer formed on the substrate material, the emitting layer capable of functioning as a light-emitting layer in a light-emitting device; and (3) a conductive paste material such as silver paste applied to the emitting layer, the conductive paste material comprising a layer of an electrode material. The layered composite may additionally comprise an appropriate buffer layer between the emitting layer and the conductive paste material. The buffer layer may be selected from the group consisting of semiconducting and conducting polymers.

The conductive paste material of the layered composite may be applied by a technique such as painting, spraying, or screen-printing. The substrate material may be selected from the group consisting of flexible ITO-coated PET and ITO-coated glass. The substrate material may also be substantially impermeable to either oxygen or water. The emitting layer may be selected from the group consisting of light emitting molecules, oligomers and polymers, their derivatives, copolymers and blends such as PPV, PPyVPV, PTP and poly(flourene)s. The semiconducting and conducting polymers may be selected from the group consisting of polyanilines, polypyrroles or blends of PPyVPV and PTP.

The electrodes of the present invention may be patterned, such as for pixelation.

Examples of conductive pastes that may be used in the present invention include: silver paste, gold paste, graphite paste, carbon paste or other particulate conductors dispersed in a medium allowing it to be applied by printing or screen printing technologies.

Examples of light emitting molecules that may be used in the emitting layer include: tris(8-quinolinolato)aluminum, bis(2-(2-hydroxyphenyl)pyridinato)beryllium, anthracene, tris(2-phenylpyridine)iridium doped in a host of 4,4′-N,N′-dicarbazol-biphenyl, their derivatives and blends thereof.

Examples of light emitting oligomers that may be used in the emitting layer include: oligo(phenylenevinylene)s, sexithiophene, oligo(thiophene)s, oligo(pyridine)s, their derivatives and blends thereof.

Examples of light emitting polymers that may be used in the emitting layer include: poly(arylene vinylene)s, poly(phenylene)s, poly(fluorene)s, poly(vinyl carbazole), poly(pyridine), poly(pyridyl vinylene), poly(phenylene vinylene pyridyl vinylene), their derivatives, their copolymers and blends thereof.

### BRIEF DESCRIPTION OF THE DRAWINGS

FIG. 1 shows repeat units of the materials of the present invention: (a) poly(pyridyl vinylene phenylene vinylene) (PPyVPV); (b) poly(thienylene phenylene) (PTP); (c) sulfonated polyaniline (SPAN).

FIG. 2 is a side elevational view of a polymer light-emitting device using silver paste as the top electrode in accordance with one embodiment of the present invention.

FIG. 3 shows the current-voltage and luminance-voltage characteristics for the ITO/PPyVPV:PTP/silver paste device of the present invention.

FIG. 4 shows a variation of the EL intensity (solid line) with time of a ITO/PPyVPV:PTP/silver paste device of the present invention.

### DETAILED DESCRIPTION OF EXEMPLARY EMBODIMENT(S)

In accordance with the foregoing summary, the following present a detailed description of the preferred embodiment of the invention that is currently considered to be the best mode.

The present invention presents a method for the fabrication of working light-emitting devices using silver paste as the cathode. This may be made possible by the presence of a buffer layer comprised of a semiconducting polymer (such as the emeraldine base form of polyaniline) or a conducting polymer, such as sulfonated polyaniline (SPAN). To eliminate the use of low work function metals, one may either use polymers with high electron affinities or modify the charge injection characteristics at the polymer/electrode interfaces.

Along these lines, a preferred embodiment of the present invention utilizes pyridine containing conjugated polymers and copolymers (which have higher electron affinities than their phenyl analogs) as the emitting materials and novel device configurations such as symmetrically configured AC light-emitting (SCALE) devices. These devices may modify the charge injection and/or transport characteristics such that their operations are insensitive to the electrode materials used. As a consequence, more stable metals such as Al or Au may be used as electrodes.

Using the novel structure of SCALE devices with a structure of substrate/ITO/emitting layer/SPAN, the top electrode may be formed simply by painting the silver paste over the SPAN layer. This may allow a very inexpensive and fast means to form a stable top electrode. When high resolution is needed, the electrode may be formed by screen printing techniques. Unlike the vacuum deposition techniques, the screen printing technique is compatible with web based processing on flexible substrate for low cost, large quantity production.

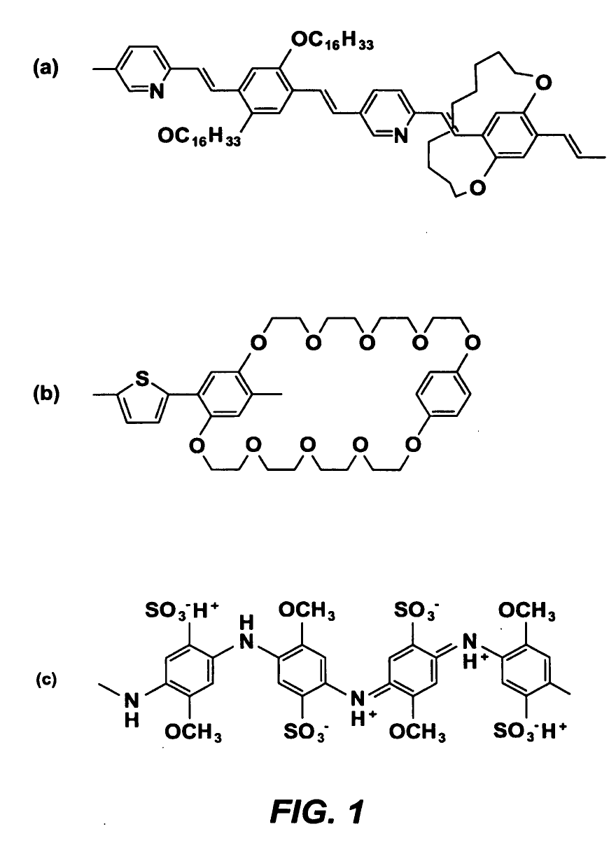

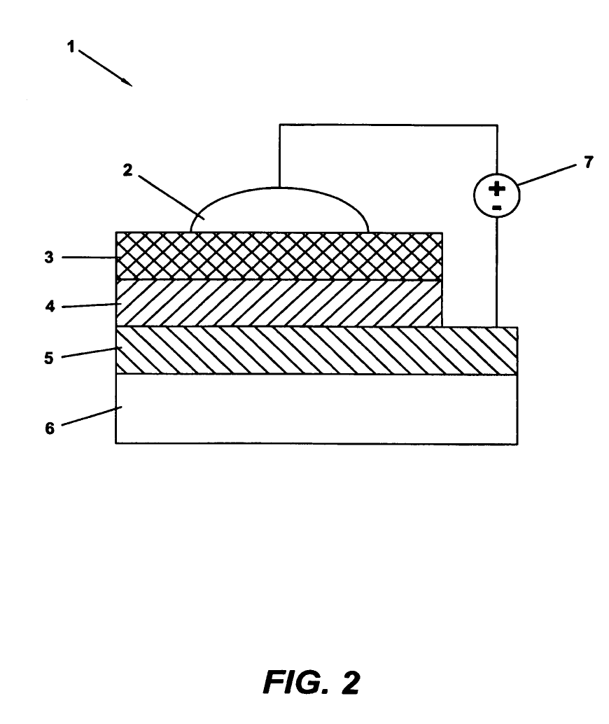

In a preferred embodiment, a copolymer of poly(pyridyl vinylene) and poly(phenylene vinylene) derivative, poly(pyridyl vinylene phenylene vinylene) (PPyVPV), and a copolymer of polythiophene and polyphenylene derivative, poly(thienylene phenylene) (PTP), may be used as the emitting materials. Blends of PPyVPV and PTP may be successfully used as active layers in SCALE devices, particularly color variable bipolar/AC light emitting devices. SPAN is a water-soluble self-doped conducting polymer with a conductivity of about 0.01 S/cm. FIG. 1 shows the chemical structures of PPyVPV, PTP and SPAN. The device structure 1 is shown schematically in FIG. 2. The PPyVPV:PTP (3:2 weight ratio) blend layer 4 may be formed by spin-casting at about 2000 rpm from trichloroethylene or xylenes solution (total concentration of about 10 mg/ml) onto a pre-cleaned patterned ITO 5 coated glass or flexible PET substrate 6. The SPAN layer 3 may be subsequently spin coated over the emitting layer 4 from an aqueous solution (50 mg/ml). In pixilated displays, in order to minimize the probability of cross-talk, a blend of SPAN and poly(vinyl alcohol) (PVA) (1:1 weight ratio) may be used to reduce the lateral conductance between the pixels. The top electrode 2 may be deposited simply by applying a silver paste, such as SPI #5063, on top of the SPAN layer 3. Care may be taken to avoid solvent penetration into the polymer layers. A driving voltage source 7 may then be connected to the anode 6 and cathode 3 layers.

In an second embodiment, blend layer 4 may be comprised of multiple sub-layers of molecules, oligomers and polymers. In such an embodiment, the electron transport layers would be closer to the cathode while the hole transport layers would be closer to the anode. Suitable electron transport layer materials may be comprised of polymeric or molecular materials. Preferred polymeric electron transport layer materials include: poly(pyridine) and poly(oxadiazole)s. Preferred molecular electron transport layer materials include: tris(8-quinolinolato)aluminum nad 2-(4′-biphenyl)-5-(4″-tert-butylphenyl)-1,3,4-oxadiazole. Similarly, suitable hole transport materials may be comprised of polymeric or molecular materials. Preferred polymeric hole transport layer materials include: poly(vinyl carbazole) and poly(arylene vinylene)s. Preferred hole transport layer materials include: aromatic diamines and starburst polyamines.

Electroluminescence may be measured using a fluorometer. The current-voltage (I-V) characteristics may be measured simultaneously with EL output while dc voltages are continuously applied. A computer may record the I-V-EL data, and quantum efficiency and brightness calculated. All device-testing procedures may be performed in air on as-made devices without any encapsulation.

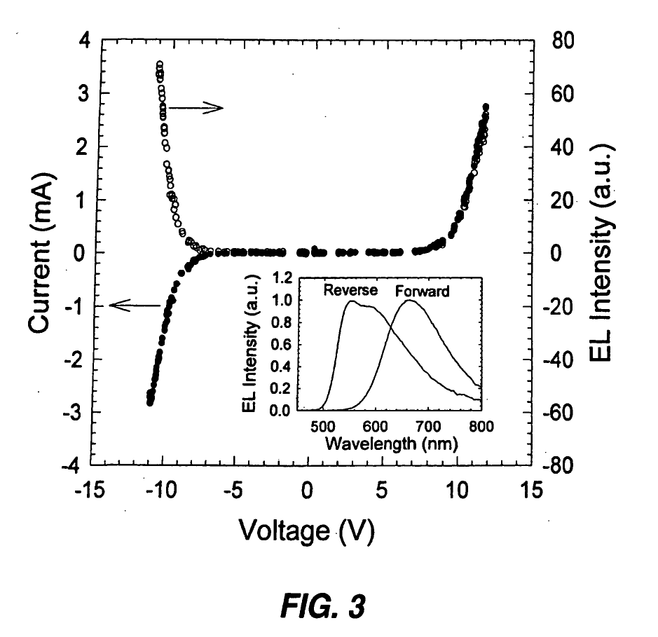

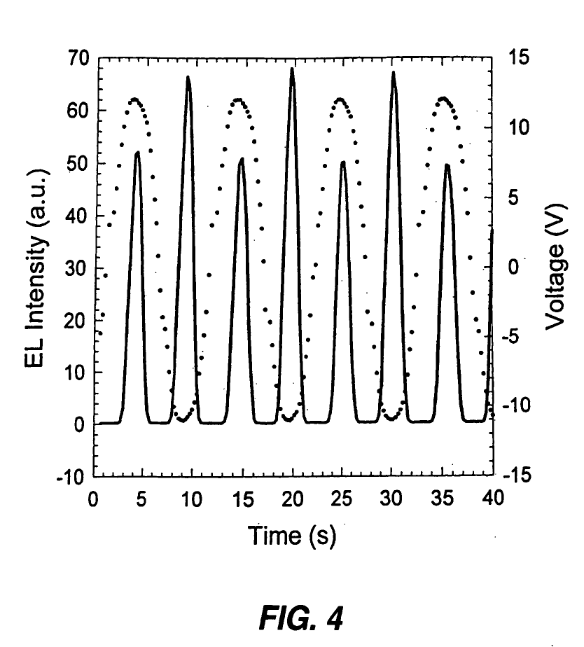

FIG. 3 shows the current-voltage and luminance-voltage characteristics of a device configured as in FIG. 2. The devices have typical turn on voltages of about 4-8 V depending upon film thickness. The devices may generate light under either polarity of driving voltage with different colors of light being emitted, red under forward bias (ITO positive) and green under reverse bias. Internal device efficiencies of about 0.1% photons/electron may be achieved for unoptimized devices. An EL spectra under forward and reverse bias are shown in the inset of FIG. 3. The colors of this device may be rapidly switched when the device is driven by an AC source. FIG. 4 shows a variation of the EL intensity with time (i.e. solid curve) when the device is driven by a 0.1 Hz sinusoidal voltage source (i.e., dotted curve).

The role of the SPAN layer in color variable SCALE devices with printable electrodes may be three-fold. First, as an acidic redox polymer it may serve as the protonation agent to protonate the PPyVPV layer producing red light. Second, being a self-doped conducting polymer, it may serve as the contacting agent (buffer layer) connecting the emitting layer and the silver paste top electrodes. Third, it may serve as a protecting agent to separate the emitting layer from direct contact with the silver paste top electrode, especially when SPAN is blended with PVA.

It may be noted that without a buffer layer such as the SPAN layer, it may be difficult to fabricate any working devices when the conducting paste is in direct contact with the emitting layer. With the presence of the SPAN layer, the performance of the devices whose top electrodes are formed simply by painting a silver paste over the SPAN layer may be comparable to those whose top electrodes are formed by conventional thermal evaporation of Al. This opens the opportunity to form top electrodes for light emitting devices using screen-printing and other deposition techniques when a suitable buffer layer such as SPAN, emeraldine base, or other conducting or semiconducting polymers can be placed between the top light emitting or charge transporting layers and the printed electrodes. Screen-printing is a well-established low cost technique that may be suitable for large area processing. Unlike the vacuum deposition techniques, when a flexible substrate is used the screen printing technique may be compatible with web based processing for low cost, large quantity production of polymer light emitting devices.

The preferred embodiments herein disclosed are not intended to be exhaustive or to unnecessarily limit the scope of the invention. The preferred embodiments were chosen and described in order to explain the principles of the present invention so that others skilled in the art may practice the invention. Having shown and described preferred embodiments of the present invention, it will be within the ability of one of ordinary skill in the art to make alterations or modifications to the present invention, such as through the substitution of equivalent materials or structural arrangements, or through the use of equivalent process steps, so as to be able to practice the present invention without departing from its spirit as reflected in the appended claims, the text and teaching of which are hereby incorporated by reference herein. It is the intention, therefore, to limit the invention only as indicated by the scope of the claims and equivalents thereof.

References

1. J. H. Burroughes, D. D. C. Bradley, A. R. Brown, R. N. Marks, K. Mackay, R. H. Friend, P. L. Bums, and A. B. Holmes, Nature 347, 539 (1990).
2. D. D. Gebler, Y. Z. Wang, J. W. Blatchford, S. W. Jessen, D.-K. Fou, T. M. Swager, A. G. MacDiarmid, and A. J. Epstein, Appl. Phys. Lett. 70, 1644 (1997).
3. Y. Z. Wang, D. D. Gebler, L. B. Lin, J. W. Blatchford, S. W. Jessen, H. L. Wang, and A. J. Epstein, Appl. Phys. Lett. 68, 894 (1996).
4. Y. Z. Wang, D. D. Gebler, D. K. Fu, T. M. Swager, and A. J. Epstein, Appl. Phys. Lett. 70, 3215 (1997).
5. Y. Z. Wang, D. D. Gebler, D. K. Fu, T. M. Swager, and A. J. Epstein, Proc. SPIE 3148, 117 (1998).
6. Y. Z. Wang, R. G. Sun, D. K. Wang, T. M. Swager, and A. J. Epstein, Appl. Phys. Lett. 74, 2593 (1999).
   The foregoing references are hereby incorporated herein by reference.

What is claimed is:

1. A layered composite capable of forming a light-emitting device, said layered composite comprising:
(a) a substrate material, said substrate material comprising a layer of an electrode material;
(b) at least one emitting layer formed on said substrate material, said at least one emitting layer capable of functioning as a light-emitting layer in a light-emitting device; and
(c) a conductive paste material applied to said emitting layer, said conductive paste material comprising a layer of an electrode material.

2. A layered composite according to claim 1 additionally comprising an appropriate buffer layer applied between said at least one emitting layer and said conductive paste material.

3. A layered composite according to claim 2 wherein said buffer layer is selected from the group consisting of semiconducting and conducting polymers.

4. A method according to claim 3 wherein said semiconducting and conducting polymers are selected from among the group consisting of polyanilines, polythiophenes, polypyrroles, their derivatives, their copolymers, and blends thereof.

5. A layered composite according to claim 1 wherein said substrate material is selected from the group consisting of flexible ITO-coated PET and ITO-coated glass.

6. A layered composite according to claim 1 wherein at least one of said at least one emitting layer comprises a light emitting molecule selected from the group consisting of tris(8-quinolinolato)aluminum, bis(2-(2-hydroxyphenyl)pyridinato)beryllium, anthracene, tris(2-phenylpyridine)iridium doped in a host 4,4′-N,N′-dicarbazol-biphenyl, their derivatives and blends thereof.

7. A layered composite according to claim 1 wherein at least one of said at least one emitting layer comprises a light emitting oligomer selected from the group consisting of oligo(phenylenevinylene)s, sexithiophene, oligo(thiophene)s, oligo(pyridine)s, their derivatives and blends thereof.

8. A layered composite according to claim 1 wherein at least one of said at least one emitting layer comprises a light emitting polymer selected from the group consisting of poly(arylene vinylene)s, poly(phenylene)s, poly(fluorene)s, poly(vinyl carbazole), poly(pyridine), poly(pyridyl vinylene), poly(phenylene vinylene pyridyl vinylene), their derivatives, their copolymers and blends thereof.

9. A layered composite according to claim 2 wherein said buffer layer is selected from the group consisting of polyanilines, polythiophenes, polypyrroles, their derivatives, copolymers and blends thereof.

10. A layered composite according to claim 1 wherein said at least one emitting layer is selected from the group consisting of blends of PPyVPV and PTP.

11. A layered composite according to claim 1 wherein said substrate material is substantially impermeable to either oxygen or water.

12. A layered composite according to claim 1 wherein said conductive paste material is selected form the group consisting of silver paste, gold paste, graphitepaste and carbon paste.
